(19) United States
(12) Patent Application Publication
(10) Pub. No.: US 2021/0313768 A1
(43) Pub. Date: Oct. 7, 2021

(54) LIGHT SOURCE APPARATUS, ADJUSTMENT METHOD, AND SENSING MODULE

(71) Applicant: Sony Semiconductor Solutions Corporation, Kanagawa (JP)

(72) Inventor: Tomonori Tsuchiyama, Kanagawa (JP)

(21) Appl. No.: 17/270,192

(22) PCT Filed: Jul. 12, 2019
(86) PCT No.: PCT/JP2019/027702

§ 371 Date: Feb. 22, 2021

(30) Foreign Application Priority Data
Aug. 31, 2018 (JP) 2018-163942

(51) Int. Cl. H01S 5/068; H01S 5/042; H01S 5/42; G01S 7/481; G01S 17/89

(52) U.S. Cl. CPC H01S 5/06808; H01S 5/042; G01S 17/89; G01S 7/4815; H01S 5/423

(57) ABSTRACT

Reduced power consumption in a light source apparatus with vertical-cavity surface-emitting laser light-emitting elements driven by a common power supply voltage is disclosed. In one example, a light source apparatus includes an emission section in which vertical-cavity surface-emitting laser light-emitting elements are arrayed, and a voltage adjustment section configured to adjust a power supply voltage used in common to drive the light-emitting elements according to a forward voltage of the light-emitting elements. This arrangement makes it possible to adjust the power supply voltage appropriately according to the forward voltage of the light-emitting elements, such as by raising the power supply voltage if the forward voltage of the light-emitting elements is high and lowering the power supply voltage if the forward voltage of the light-emitting elements is low.

### TECHNICAL FIELD

The present technology relates to a light source apparatus provided with an emission section in which a plurality of vertical-cavity surface-emitting laser light-emitting elements is arrayed, an adjustment method that adjusts a power supply voltage used to drive the light-emitting elements, and a sensing module provided with an image sensor that captures an image by receiving light that is emitted by the emission section and then reflected by a subject.

### BACKGROUND ART

The vertical-cavity surface-emitting laser (VCSEL) is known as a light-emitting element that emits laser light (see Patent Literatures 1 and 2 below, for example).

A VCSEL light-emitting element is configured such that an oscillator is formed perpendicular to the semiconductor substrate surface and laser light is emitted in the perpendicular direction, and in recent years, VCSELs have been used widely as light sources when measuring the distance to a subject according to a structured light (STL) method and a time of flight (ToF) method, for example.

### CITATION LIST

### Patent Document

Patent Document 1: Japanese Patent Application Laid-Open No. 2012-195436
Patent Document 2: Japanese Patent Application Laid-Open No. 2015-103727

### SUMMARY OF THE INVENTION

### Problems to be Solved by the Invention

Here, in the case of measuring the distance to a subject according to an STL method or a ToF method, a light source apparatus in which a plurality of VCSEL light-emitting elements is disposed in a two-dimensional array is used. Specifically, the subject is illuminated with light emitted from the plurality of light-emitting elements, and the distance to the subject is measured on the basis of an image obtained by receiving reflected light from the subject.

At this point, it is conceivable to drive the plurality of light-emitting elements on the basis of a common power supply voltage. By using a common power supply voltage, the power supply circuit can be shared in common, and improvements such as a reduced number of circuit components and a reduced circuit mounting area may be attained.

However, VCSEL light-emitting elements exhibit individual variations in the forward voltage (VF). For this reason, in the case of a configuration that drives a plurality of light-emitting elements on the basis of a common power supply voltage, if the magnitude of the power supply voltage is not set appropriately, there is a risk that some of the light-emitting elements may not emit light. For example, if the range of variation in the forward voltage is estimated to be relatively narrow and a low power supply voltage is set, but some of the light-emitting elements have an unexpectedly high forward voltage, there is a risk of being unable to cause those light-emitting elements to emit light appropriately. On the other hand, if the range of variation in the forward voltage is estimated to be relatively wide, setting a high power supply voltage is effective at enabling all of the light-emitting elements to emit light appropriately, but this also leads to increased power consumption, which is undesirable.

The present technology has been devised in light of the above circumstances, and an object is to attain a reduction in power consumption while also enabling all light-emitting elements to emit light appropriately in a configuration that drives a plurality of vertical-cavity surface-emitting laser light-emitting elements on the basis of a common power supply voltage.

### Solutions to Problems

A light source apparatus according to the present technology includes an emission section in which a plurality of vertical-cavity surface-emitting laser light-emitting elements is arrayed, and a voltage adjustment section configured to adjust a power supply voltage used in common to drive the plurality of light-emitting elements in the emission section described above according to a forward voltage of the light-emitting elements described above.

This arrangement makes it possible to adjust the power supply voltage appropriately according to the forward voltage of the light-emitting elements, such as by raising the power supply voltage if the forward voltage of the light-emitting elements is high and lowering the power supply voltage if the forward voltage of the light-emitting elements is low.

The light source apparatus according to the present technology described above, it is desirable that the voltage adjustment section be configured to adjust the power supply voltage according to a highest forward voltage among the plurality of light-emitting elements.

With this arrangement, the common power supply voltage is adjusted according to the forward voltage of the light-emitting element having the highest forward voltage.

The light source apparatus the present technology described above, it is desirable to include a driving section configured to drive the plurality of light-emitting elements individually on the basis of the power supply voltage.

With this arrangement, it is possible to turn on some of the plurality of light-emitting elements sharing the power supply voltage while turning off the other light-emitting elements, and the light-emitting element having the highest forward voltage may be turned off. By turning off the light-emitting element having the highest forward voltage, the power supply voltage is adjusted according to the forward voltage of the light-emitting elements having a lower forward voltage.

The light source apparatus according to the present technology described above, it is desirable to include a current mirror circuit configured to send a constant current to the plurality of light-emitting elements on the basis of the power supply voltage.

With this arrangement, it is not necessary to use a power supply circuit with a constant current control function to send a constant current to the light-emitting elements.

The light source apparatus according to the present technology described above, it is desirable that the current mirror circuit be connected to an anode side of the light-emitting elements, and that the voltage adjustment section be configured to adjust the power supply voltage according to a voltage at an anode of the light-emitting elements.

This arrangement makes it possible to adjust the power supply voltage appropriately according to the forward voltage of the light-emitting elements in a case where the current mirror circuit is connected on the anode side of the light-emitting elements.

The light source apparatus according to the present technology described above, it is desirable that the current mirror circuit be connected to a cathode side of the light-emitting elements, and that the voltage adjustment section be configured to adjust the power supply voltage according to a voltage at a cathode of the light-emitting elements.

This arrangement makes it possible to adjust the power supply voltage appropriately according to the forward voltage of the light-emitting elements in a case where the current mirror circuit is connected on the cathode side of the light-emitting elements.

The light source apparatus according to the present technology described above, it is desirable that the voltage adjustment section be configured to adjust the power supply voltage according to the forward voltage of the light-emitting elements and an operating voltage of a driving element in the current mirror circuit.

With this arrangement, the power supply voltage is adjusted appropriately according to the forward voltage of the light-emitting elements and the operating voltage of the driving elements, in correspondence with the case of providing the current mirror circuit.

The light source apparatus according to the present technology described above, it is desirable to include a driving section configured to drive the plurality of light-emitting elements on the basis of the power supply voltage, in which the driving section and the voltage adjustment section are formed in a same chip.

This arrangement makes it possible to use in-chip wiring to form the detection lines for detecting and inputting the forward voltage of each of the light-emitting elements into the voltage adjustment section.

The light source apparatus according to the present technology described above, it is desirable that the emission section include a plurality of light-emitting element groups, each including a plurality of the light-emitting elements, and that the voltage adjustment section be configured to adjust a power supply voltage shared within each light-emitting element group according to the forward voltage for each light-emitting element group.

In the case of taking a configuration that adjusts a power supply voltage shared in common within a light-emitting element group individually for each light-emitting element group in this way, to enable all of the light-emitting elements in the emission section to emit light appropriately, it is sufficient to adjust each power supply voltage to suit the highest forward voltage in the corresponding light-emitting element group to be supplied with each power supply voltage, and it is not necessary to adjust each power supply voltage to suit the highest forward voltage from among all of the light-emitting elements in the emission section.

Also, an adjustment method according to the present technology is a method of adjusting the power supply voltage used in common to drive a plurality of light-emitting elements in an emission section in which a plurality of vertical-cavity surface-emitting laser light-emitting elements is arrayed, in which the power supply voltage is adjusted according to the forward voltage of the light-emitting elements.

Furthermore, a sensing module according to the present technology includes the light source apparatus according to the present technology described above, and an image sensor that captures an image by receiving light that is emitted by the emission section provided in the light source apparatus and then reflected by a subject.

Action similar to the light source apparatus according to the present technology described above are also obtained by such a detection method and sensing module.

### Effects of the Invention

According to the present technology, a reduction in power consumption may be attained while also enabling all light-emitting elements to emit light appropriately in a configuration that drives a plurality of vertical-cavity surface-emitting laser light-emitting elements on the basis of a common power supply voltage.

Note that, the effect described here is not necessarily limited, and can be any effect described in the present disclosure.

### BRIEF DESCRIPTION OF DRAWINGS

FIG. 1 is a diagram illustrating an exemplary configuration of a distance measuring apparatus as an embodiment of a light source apparatus according to the present technology.

FIG. 2 is a diagram explaining a technique of measuring distance according to a structured light (STL) method.

FIG. 3 is a diagram illustrating an exemplary circuit configuration of the light source apparatus as an embodiment.

FIG. 4 is a diagram illustrating a modification of a driving circuit provided in the light source apparatus as an embodiment.

FIG. 5 is a diagram illustrating an exemplary substrate configuration of the light source apparatus as an embodiment.

FIG. 6 is a diagram illustrating another exemplary substrate configuration of the light source apparatus as an embodiment.

FIG. 7 is a diagram illustrating yet another exemplary substrate configuration of the light source apparatus as an embodiment.

FIG. 8 is a diagram illustrating an exemplary arrangement of temperature sensors provided in the light source apparatus as an embodiment.

FIG. 9 is a diagram illustrating an exemplary structure of an emission section provided in the light source apparatus as an embodiment.

FIG. 10 is a diagram illustrating another exemplary structure of an emission section provided in the light source apparatus as an embodiment.

FIG. 11 is a diagram for explaining an example of setting the power supply voltage in the related art.

FIG. 12 is a diagram for explaining an example of adjusting the power supply voltage as an embodiment.

FIG. 13 is a diagram for explaining the adjustment of the power supply voltage in the case where the emission section is made to emit light in a plurality of emission modes having different emission patterns.

FIG. 14 is a diagram for explaining an exemplary internal configuration of a voltage adjustment section for achieving the power supply voltage adjustment as an embodiment.

FIG. 15 is a diagram for explaining another example of the internal configuration of the voltage adjustment section.

FIG. 16 is a diagram illustrating an exemplary internal configuration of a differential amplifier provided in the voltage adjustment section illustrated in FIG. 15.

FIG. 17 is a diagram illustrating an exemplary configuration of a light source apparatus according to a modification.

### MODE FOR CARRYING OUT THE INVENTION

Hereinafter, the attached drawings will be referenced to describe embodiments according to the present technology in the following order.

<1. Configuration of distance measuring apparatus>

<2. Distance measuring techniques>

<3. Circuit configuration related to emission driving>

<4. Variations in substrate configuration>

<5. Exemplary VCSEL structure>

<6. Adjustment of power supply voltage>

<7. Summary of embodiment and modifications>

<8. Present technology>

<1. Configuration of Distance Measuring Apparatus>

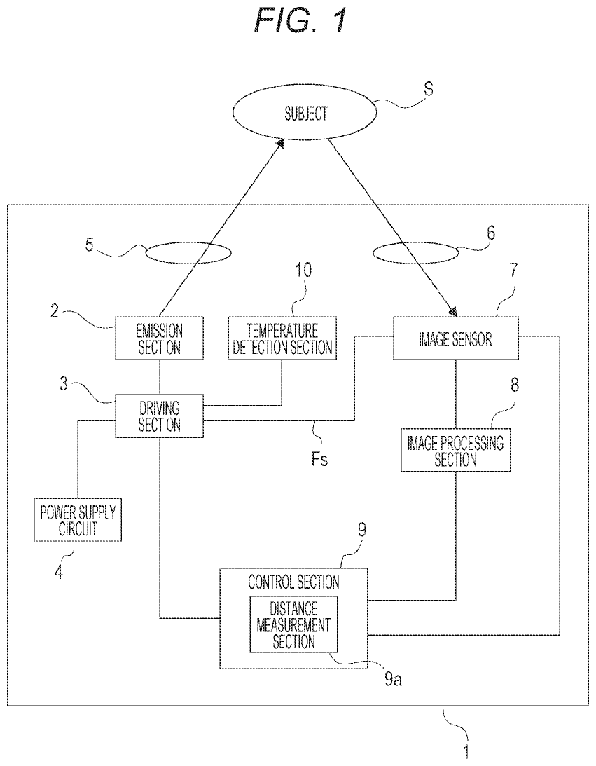

FIG. 1 illustrates an exemplary configuration of a distance measuring apparatus 1 as an embodiment of a light source apparatus according to the present technology.

As illustrated in the diagram, the distance measuring apparatus 1 is provided with an emission section 2, a driving section 3, a power supply circuit 4, an emission-side optical system 5, an imaging-side optical system 6, an image sensor 7, an image processing section 8, a control section 9, and a temperature detection section 10.

The emission section 2 emits light from a plurality of light sources. As described later, the emission section 2 in this example includes vertical-cavity surface-emitting laser (VCSEL) light-emitting elements 2a as the light sources, and these light-emitting elements 2a are arrayed in a predetermined pattern, such as a matrix for example.

The driving section 3 includes an electrical circuit for driving the emission section 2.

The power supply circuit 4 generates a power supply voltage for the driving section 3 (a power supply voltage Vs described later) on the basis of an input voltage (an input voltage Vin described later) from a source such as a battery not illustrated that is provided in the distance measuring apparatus 1, for example. The driving section 3 drives the emission section 2 on the basis of the power supply voltage.

Light emitted by the emission section 2 illuminates, through the emission-side optical system 5, a subject S treated as the target of distance measurement. Thereafter, reflected light from the subject S out of the light emitted in this way is incident on the imaging surface of the image sensor 7 through the imaging-side optical system 6.

The image sensor 7 is an image sensor such as a charge-coupled device (CCD) sensor or a complementary metal-oxide semiconductor (CMOS) sensor for example that receives reflected light from the subject S incident through the imaging-side optical system 6 as above, and converts the received light to output an electrical signal.

The image sensor 7 executes processes such as a correlated double sampling (CDS) process and an automatic gain control (AGC) process on the electrical signal obtained by photoelectric conversion of the received light, and furthermore performs an analog/digital (A/D) conversion process. An image signal is then output as digital data to the image processing section 8 downstream.

Additionally, the image sensor 7 in this example outputs a frame synchronization signal Fs to the driving section 3. With this arrangement, the driving section 3 is capable of causing the light-emitting elements 2a in the emission section 2 to emit light at timings according to the frame cycle of the image sensor 7.

The image processing section 8 is configured as an image processor such as a digital signal processor (DSP), for example. The image processing section 8 performs various types of image signal processing on the digital signal (image signal) input from the image sensor 7.

The control section 9 is provided with an information processing device such as a microcomputer including components such as a central processing unit (CPU), read-only memory (ROM), and random access memory (RAM), or a DSP. The control section 9 controls the driving section 3 for controlling the emission operations by the emission section 2 and controls imaging operations by the image sensor 7.

The control section 9 includes functions that act as a distance measurement section 9a. The distance measurement section 9a measures the distance to the subject S on the basis of the image signal input through the image processing section 8 (that is, the image signal obtained by receiving reflected light from the subject S). The distance measurement section 9a in this example measures the distance to different portions of the subject S, thereby making it possible to identify the three-dimensional shape of the subject S.

Herein, specific techniques of measuring distance in the distance measuring apparatus 1 will be described in further detail later.

The temperature detection section 10 detects the temperature of the emission section 2. A configuration that detects temperature using a diode for example can be adopted as the temperature detection section 10.

In this example, information about the temperature detected by the temperature detection section 10 is supplied to the driving section 3, thereby enabling the driving section 3 to drive the emission section 2 on the basis of the information about the temperature.

<2. Distance Measuring Techniques>

As the technique of measuring distance in the distance measuring apparatus 1, a technique of measuring distance according to a structured light (STL) method or a time of flight (ToF) method can be adopted, for example.

The STL method measures distance on the basis of an image obtained by imaging the subject S illuminated with light having a predetermined light/dark pattern, such as a dot pattern or a grid pattern, for example.

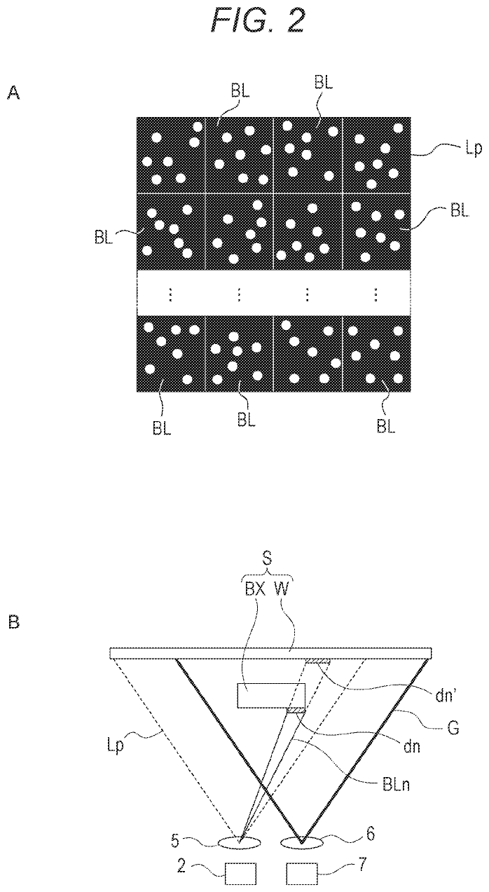

FIG. 2 is a diagram explaining the STL method.

In the STL method, the subject S is illuminated with pattern light Lp having a dot pattern like the one illustrated in FIG. 2A, for example. The pattern light Lp is divided into a plurality of blocks BL, and a different dot pattern is assigned to each block BL (the dot patterns are not duplicated among the blocks BL).

FIG. 2B is a diagram explaining the principle of distance measurement according to the STL method.

In the example herein, a wall W and a box BX placed in front are treated as the subject S, and the subject S is illuminated with pattern light Lp. In the diagram, “G” schematically represents the angle of view of the image sensor 7.

Also, “BLn” in the diagram means the light from a certain block BL among the pattern light Lp, and “dn” means the dot pattern of the block BLn appearing in the captured image obtained by the image sensor 7.

Here, in the case where the box BX in front of the wall W does not exist, the dot pattern of the block BLn appears in the captured image at a position “dn′” in the diagram. In other words, the position where the pattern of the block BLn appears in the captured image is different between the case where the box BX exists and the case where the box BX does not exist, and more specifically, a distortion in the pattern occurs.

The STL method is a method of obtaining the shape and the depth of the subject S by utilizing how the illuminating pattern is distorted by the physical shape of the subject S in this way. Specifically, the STL method is a method of obtaining the shape and the depth of the subject S from the way in which the pattern is distorted.

In the case of adopting the STL method, an infrared (IR) image sensor with a global shutter is used as the image sensor 7, for example. Additionally, in the case of the STL method, the distance measurement section 9a controls the driving section 3 such that the emission section 2 emits pattern light, and in addition, detects pattern distortion in the image signal obtained through the image processing section 8, and calculates the distance on the basis of the way in which the pattern is distorted.

Next, the ToF method measures the distance to a target by detecting the time of flight (time difference) of light that is emitted by the emission section 2, reflected by the target, and arrives at the image sensor 7.

In the case of adopting what is called the direct ToF method as the ToF method, a single-photon avalanche diode (SPAD) is used as the image sensor 7, and the emission section 2 is pulse-driven. In this case, the distance measurement section 9a calculates the time difference from emission to reception for light that is emitted by the emission section 2 and received by the image sensor 7 on the basis of the image signal input through the image processing section 8, and calculates the distance to different portions of the subject S on the basis of the time difference and the speed of light.

Note that in the case of adopting what is called the indirect ToF method (phase difference method) as the ToF method, an IR image sensor is used as the image sensor 7, for example.

<3. Circuit Configuration Related to Emission Driving>

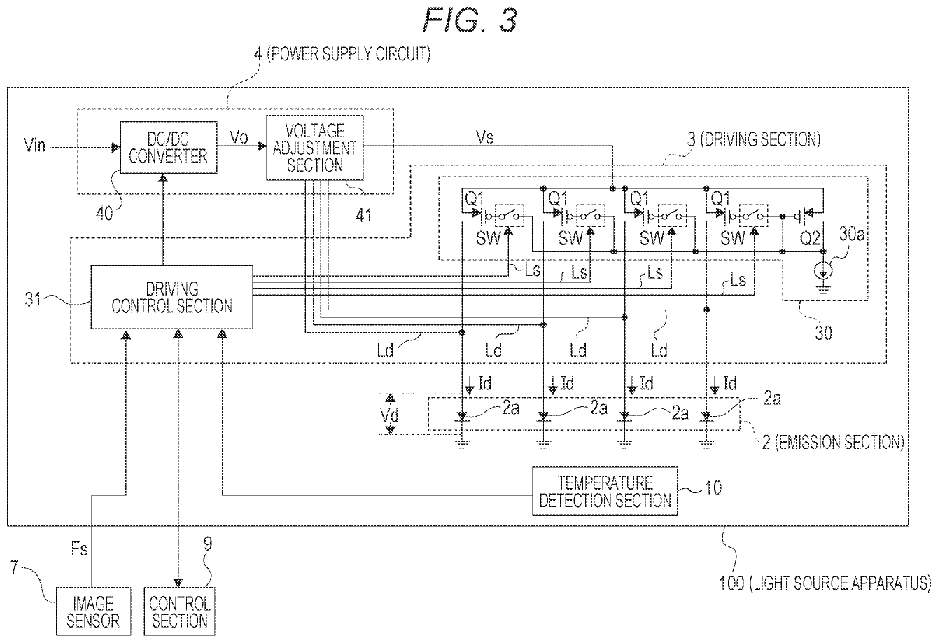

FIG. 3 illustrates an exemplary circuit configuration of a light source apparatus 100 that includes the emission section 2, the driving section 3, and the power supply circuit 4 illustrated in FIG. 1. Note that in addition to the exemplary circuit configuration of the light source apparatus 100, FIG. 3 also illustrates the image sensor 7 and the control section 9 illustrated in FIG. 1.

In this example, the emission section 2, the driving section 3, and the power supply circuit 4 are formed on a common substrate (a substrate B described later). Here, the configuration unit that includes at least the emission section 2 and is formed on a common substrate with the emission section 2 is referred to as the light source apparatus 100.

As illustrated in the diagram, the light source apparatus 100 is provided with the temperature detection section 10 in addition to the emission section 2, the driving section 3, and the power supply circuit 4.

The emission section 2 is provided with a plurality of VCSEL light-emitting elements 2a as described earlier. In FIG. 3, the number of light-emitting elements 2a is treated as “4” for convenience, but the number of light-emitting elements 2a in the emission section 2 is not limited thereto, and is sufficiently at least two or more.

The power supply circuit 4 is provided with a DC/DC converter 40 and a voltage adjustment section 41. The DC/DC converter 40 generates a direct-current (DC) output voltage Vo on the basis of an input voltage Vin supplied as a DC voltage. The voltage adjustment section 41 generates, on the basis of the output voltage Vo, a power supply voltage Vs that the driving section 3 uses to drive the emission section 2. Here, the voltage adjustment section 41 includes a function of adjusting the power supply voltage Vs, which will be described in further detail later.

The driving section 3 is provided with a driving circuit 30 and a driving control section 31.

The driving circuit 30 includes a driving element Q1 and a switch SW for each light-emitting element 2a, as well as a current control element Q2 and a constant current source 30a.

A field-effect transistor (FET) is used for the driving element Q1 and the current control element Q2, and in this example, a P-channel metal-oxide-semiconductor (MOS) FET, or MOSFET, is used.

The driving elements Q1 are connected in a parallel relationship with respect to the output line of the power supply circuit 4, or in other words the supply line of the power supply voltage Vs, and the current control element Q2 is connected in parallel with the driving elements Q1.

Specifically, the source of each of the driving elements Q1 and the current control element Q2 is connected to the output line of the power supply circuit 4. The drain of each driving element Q1 is connected to the anode of a corresponding light-emitting element 2a among the light-emitting elements 2a in the emission section 2.

As illustrated in the diagram, the cathode of each light-emitting element 2a is connected to ground (GND).

The drain of the current control element Q2 is connected to ground through the constant current source 30a, while the gate is connected to the node between the drain and the constant current source 30a.

The gate of each driving element Q1 is connected to the gate of the current control element Q2 through a corresponding switch SW.

In the driving circuit 30 having the above configuration, the driving elements Q1 whose switch SW is ON are electrically conductive, the driving voltage Vd based on the output voltage Vo is applied to the light-emitting elements 2a connected to the electrically conductive driving elements Q1, and the light-emitting elements 2a emit light.

At this time, a driving current Id flows to the light-emitting elements 2a, but in the driving circuit 30 having the above configuration, the driving elements Q1 and the current control element Q2 form a current mirror circuit, and the current value of the driving current Id is controlled by a value corresponding to the current value of the constant current source 30a.

By controlling the ON/OFF state of the switches SW in the driving circuit 30, the driving control section 31 controls the ON/OFF state of the light-emitting elements 2a. In the diagram, the control signal lines by which the driving control section 31 individually controls the ON/OFF state of each of the switches SW are labeled the control signal lines Ls.

The frame synchronization signal Fs is supplied to the driving control section 31 by the image sensor 7, thereby enabling the driving control section 31 to synchronize the ON timings and OFF timings of the light-emitting elements 2a with the frame cycle of the image sensor 7.

Additionally, the driving control section 31 is capable of controlling the ON/OFF state of the light-emitting elements 2a on the basis of an instruction from the control section 9.

Additionally, the driving control section 31 is configured to be capable of controlling the ON/OFF state of the light-emitting elements 2a and the operation of the DC/DC converter 40 on the basis of the temperature of the emission section 2 detected by the temperature detection section 10.

As illustrated in the diagram, in the driving section 3, a detection line Ld for detecting the voltage (the forward voltage (VF)) produced in each light-emitting element 2a is formed for each light-emitting element 2a. Specifically, in the configuration illustrated in FIG. 3, each detection line Ld is connected to the anode of the corresponding light-emitting element 2a.

In this example, the voltage adjustment section 41 in the power supply circuit 4 accepts the input of the voltage obtained from each detection line Ld. As described later, the voltage adjustment section 41 adjusts the power supply voltage Vs on the basis of the forward voltage of each light-emitting element 2a input through each detection line Ld in this way.

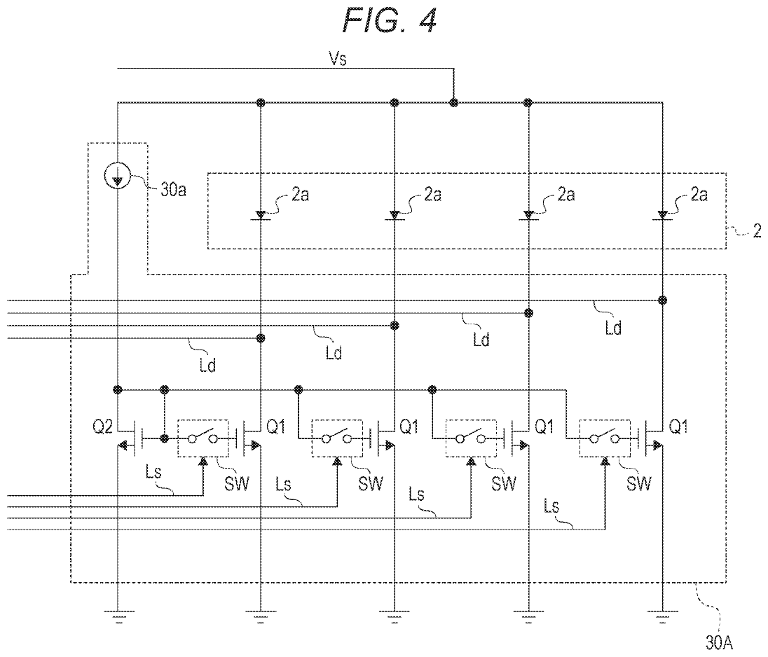

Here, FIG. 3 illustrates an example of a configuration in which a current mirror circuit containing the driving elements Q1 and the current control element Q2 is provided on the anode side of the light-emitting elements 2a, but like the driving circuit 30A illustrated in FIG. 4, a configuration in which the current mirror circuit is provided on the cathode side of the light-emitting elements 2a is also possible.

In this case, the anode of each light-emitting element 2a in the emission section 2 is connected to the output line of the power supply circuit 4.

In this case, an N-channel MOSFET is used for each of the driving elements Q1 and the current control element Q2 forming the current mirror circuit. The drain and the gate of the current control element Q2 is connected to the output line of the power supply circuit 4 through the constant current source 30a, while the source is connected to ground.

The drain of each driving element Q1 is connected to the cathode of the corresponding light-emitting element 2a, while the source is connected to ground. The gate of each driving element Q1 is connected to the gate and the drain of the current control element Q2 through each corresponding switch SW.

In this case as well, by controlling the ON/OFF state of the switches SW, the driving control section 31 can turn the light-emitting elements 2a ON/OFF.

Also, in this case, each detection line Ld is connected to the cathode of the corresponding light-emitting element 2a, in correspondence with the current mirror circuit being connected on the cathode side of the light-emitting elements 2a. In other words, the driving control section 31 in this case detects the voltage at the cathode of the light-emitting elements 2a.

<4. Variations in Substrate Configuration>

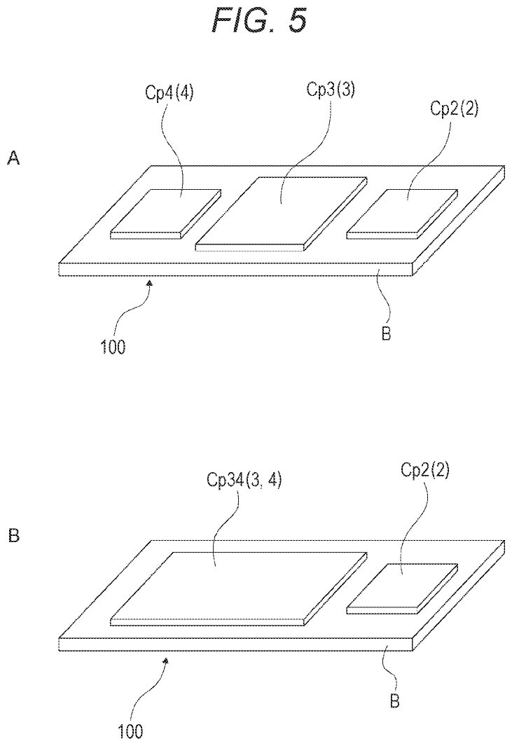

Here, the light source apparatus 100 may take the configurations illustrated in FIGS. 5 to 7.

As illustrated in FIG. 5A, the light source apparatus 100 may take a configuration in which a chip Cp2 containing a circuit that acts as the emission section 2, a chip Cp3 containing a circuit that acts as the driving section 3, and a chip Cp4 containing the power supply circuit 4 are formed on the same substrate B.

Additionally, the driving section 3 and the power supply circuit 4 may also be formed in the same chip Cp34, and in this case, the light source apparatus 100 may take a configuration in which the chip Cp2 and the chip Cp34 are formed on the same substrate B, as illustrated in FIG. 5B.

It is also possible to take a configuration in which a chip Cp is mounted on another chip Cp.

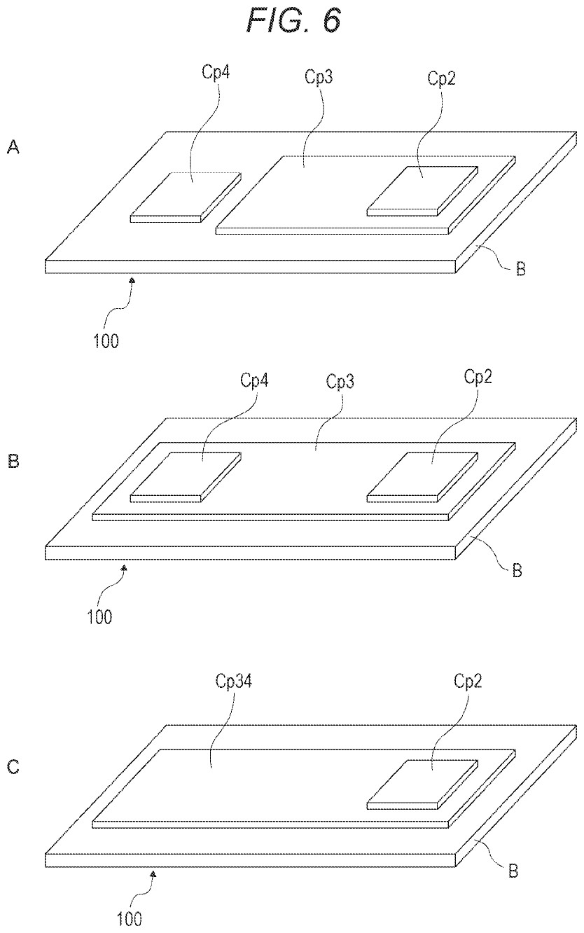

In this case, the light source apparatus 100 may take a configuration in which the chip Cp3 having the chip Cp2 mounted thereon and the chip Cp4 are formed on the substrate B like in FIG. 6A, a configuration in which the chip Cp3 having the chip Cp2 and the chip Cp4 mounted thereon is formed on the substrate B like in FIG. 6B, or a configuration in which the chip Cp34 having the chip Cp2 mounted thereon is formed on the substrate B like in FIG. 6C, for example.

Additionally, the light source apparatus 100 may also take a configuration that includes the image sensor 7.

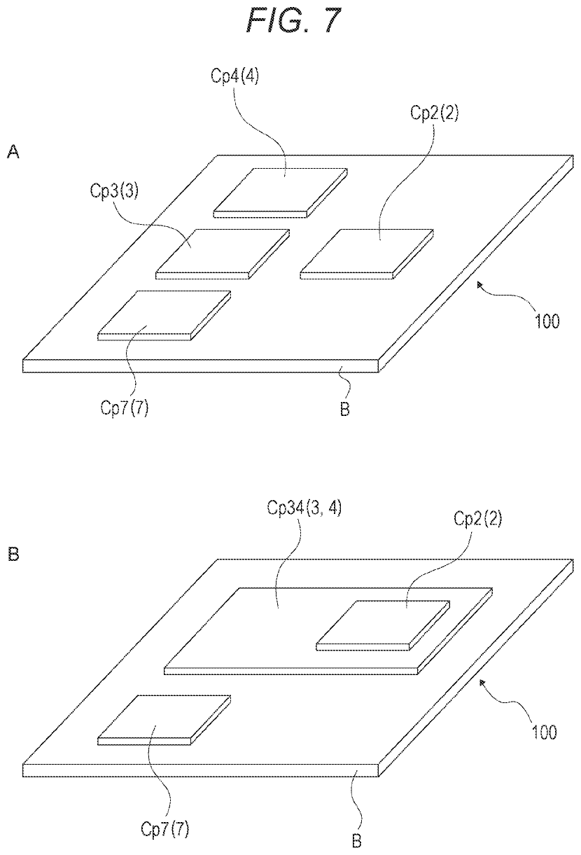

For example, FIG. 7A illustrates an example of a configuration of the light source apparatus 100 in which the chip Cp2, the chip Cp3, and the chip Cp4 as well as a chip Cp7 containing a circuit that acts as the image sensor 7 are formed on the same substrate B.

Also, FIG. 7B illustrates an example of a configuration of the light source apparatus 100 in which the chip Cp34 having the chip Cp2 mounted thereon and the chip Cp7 are formed on the same substrate B.

Here, regarding the temperature detection section 10, in the case where the chip Cp2 is formed on the substrate B like in FIGS. 5A, 5B, and 7A for example, it is sufficient to form temperature detection elements such as diodes at positions near the chip Cp2 in the substrate B (such as positions beside the chip Cp2 on the substrate B, for example).

Also, in the case where the chip Cp2 is mounted onto another chip Cp like in FIGS. 6A to 6C and FIG. 7B, it is sufficient to form the temperature detection elements at positions near the chip Cp2 in the other chip Cp (such as positions underneath of the chip Cp2, for example).

The temperature detection section 10 may include a plurality of temperature sensors 10a including temperature detection elements such as diodes.

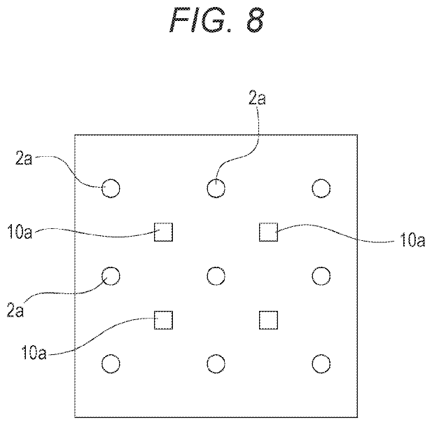

FIG. 8 illustrates an exemplary arrangement of the temperature sensors 10a in the case where the temperature detection section 10 includes a plurality of temperature sensors 10a.

In the example of FIG. 8, the plurality of temperature sensors 10a are not concentrated in a single location, but are dispersed in a plane parallel to the plane in which the light-emitting elements 2a are arrayed. Specifically, the plurality of temperature sensors 10a may be arranged such that one temperature sensor 10a is disposed for each emission block containing a predetermined number of light-emitting elements 2a, such as a 2×2 block containing a total of four light-emitting elements 2a, for example. In this case, the temperature sensors 10a may be arranged at equal intervals in a plane parallel to the plane in which the light-emitting elements 2a are arrayed.

Note that although FIG. 8 illustrates an example of arranging four temperature sensors 10a with respect to nine light-emitting elements 2a, but the number of disposed light-emitting elements 2a and the number of disposed temperature sensors 10a are not limited thereto.

Also, by dispersing the plurality of temperature sensors 10a like in the examples of FIG. 8, it is possible to detect an in-plane temperature distribution of the emission section 2. In addition, different temperatures can be detected for different areas of the emission surface, and furthermore, by increasing the number of disposed temperature sensors 10a, it is also possible to detect different temperatures for each of the light-emitting elements 2a.

<5. Exemplary VCSEL Structure>

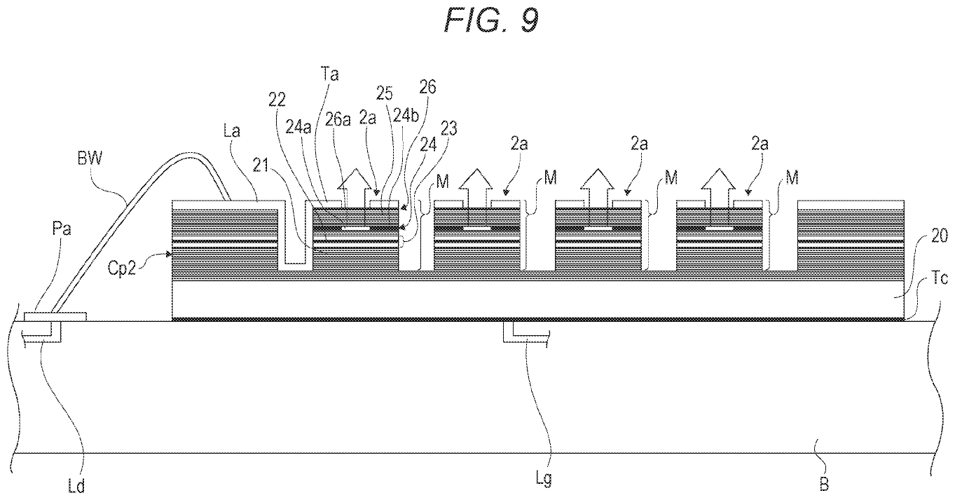

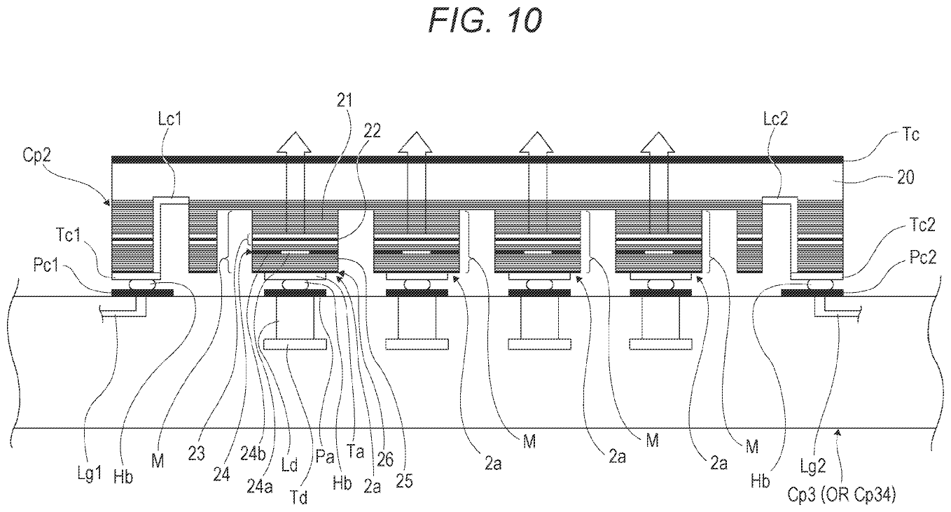

Next, an exemplary structure of the chip Cp2 in which the emission section 2 is formed will be described with reference to FIGS. 9 and 10.

FIG. 9 illustrates an exemplary structure of the chip Cp2 in the case of being formed on the substrate B like in FIGS. 5A, 5B, and 5A, while FIG. 10 illustrates an exemplary structure of the chip Cp2 in the case of being mounted onto another chip Cp like in FIGS. 6A to 6C and FIG. 7B.

Note that, as an example, FIGS. 9 and 10 illustrate an exemplary structure corresponding to the case where the driving circuit 30 (current mirror circuit) is inserted on the anode side of the light-emitting elements 2a (see FIG. 3).

As illustrated in FIG. 9, in the chip Cp2, the portions corresponding to each of the light-emitting elements 2a are formed as mesas M.

A semiconductor substrate 20 is used as the substrate of the chip Cp2, and a cathode electrode Tc is formed on the underside of the semiconductor substrate 20. For the semiconductor substrate 20, a gallium arsenide (GaAs) substrate is used, for example.

On the semiconductor substrate 20, in each mesa M, a first multilayer reflective layer 21, an active layer 22, a second multilayer reflective layer 25, a contact layer 26, and an anode electrode Ta are formed in order from bottom to top.

A current constriction layer 24 is formed in a part (specifically the lower part) of the second multilayer reflective layer 25. Also, the portion including the active layer 22 that is sandwiched between the first multilayer reflective layer 21 and the second multilayer reflective layer 25 acts as a resonator 23.

The first multilayer reflective layer 21 is formed using a compound semiconductor exhibiting N-type conductivity, while the second multilayer reflective layer 25 is formed using a compound semiconductor exhibiting P-type conductivity.

The active layer 22 acts as a layer for generating laser light, while the current constriction layer 24 acts as a layer that injects current efficiently into the active layer 22 and achieves a lens effect.

After the mesas M are formed, the current constriction layer 24 is subjected to selective oxidation in the unoxidized state, and includes a central oxidized region (also referred to as a selectively oxidized region) 24a and an unoxidized region 24b that is not oxidized in the periphery of the oxidized region 24a. In the current constriction layer 24, a current constricting structure is formed by the oxidized region 24a and the unoxidized region 24b, and current is conducted to the current constriction region as the unoxidized region 24b.

The contact layer 26 is provided to ensure an ohmic contact with the anode electrode Ta.

The anode electrode Ta is formed on the contact layer 26 in an annular (ring) shape or the like that is open in the center for example when looking at a plan view of the substrate B. In the contact layer 26, the portion where the anode electrode Ta is not formed on top acts as an opening 26a.

Light generated in the active layer 22 travels back and forth inside the resonator 23 and then is emitted to the outside through the opening 26a.

Here, the cathode electrode Tc in the chip Cp2 is connected to ground through a ground lead Lg formed in a wiring layer of the substrate B.

Also, in the diagram, a pad Pa represents a pad for the anode electrode formed on the substrate B. The pad Pa is connected to the drain of any one of the driving elements Q1 included in the driving circuit 30 through a lead Ld formed in the wiring layer of the substrate B.

In the diagram, the anode electrode Ta is illustrated as being connected to the single pad Pa through an anode lead La formed on the chip Cp2 and a bonding wire BW for only one light-emitting element 2a, but the pad Pa and the lead Ld are formed for each light-emitting element 2a on the substrate B, and furthermore, the anode lead La is formed for each of the light-emitting elements 2a on the chip Cp2, and the anode electrodes Ta of the individual light-emitting elements 2a are connected to the corresponding pad Pa through the corresponding anode lead La and bonding wire BW.

Next, in the case of FIG. 10, a back-illumination chip Cp2 is used as the chip Cp2. In other words, rather than emitting light in the upward direction (surface direction) of the semiconductor substrate 20 like the example in FIG. 9, a chip Cp2 of a type that emits light in the back direction of the semiconductor substrate 20.

In this case, an opening for emitting light is not formed in the anode electrode Ta, and the opening 26a is not formed in the contact layer 26.

In the chip Cp3 (or the chip Cp34; the same applies hereinafter in the description of FIG. 10) in which the driving section 3 (driving circuit 30) is formed, the pad Pa for establishing an electrical connection with the anode electrode Ta is formed for each light-emitting element 2a. In the wiring layer of the chip Cp3, the lead Ld is formed for each pad Pa. Although omitted from illustration, each of the pads Pa is connected, by these leads Ld, to the drain of a corresponding driving element Q1 in the driving circuit 30 formed in the chip Cp3.

Also, in the chip Cp2, the cathode electrode Tc is connected to an electrode Tc1 and an electrode Tc2 via leads Lc1 and Lc2, respectively. The electrode Tc1 and the electrode Tc2 are electrodes for respectively connecting with a pad Pc1 and a pad Pc2 formed in the chip Cp3.

In the wiring layer of the chip Cp3, a ground lead Lg1 connected to the pad Pc1 and a ground lead Lg2 connected to the pad Pc2 are formed. Although not illustrated, these ground leads Lg1 and Lg2 are connected to ground.

The connections between each anode electrode Ta in the chip Cp2 and each pad Pa in the chip Cp3 as well as the connections between the electrodes Tc1 and Tc2 in the chip Cp2 and the pads Pc1 and Pc2 in the chip Cp3 are established through respective solder bumps Hb.

In other words, the mounting of the chip Cp2 on the chip Cp3 in this case is achieved by what is called flip chip mounting.

<6. Adjustment of Power Supply Voltage>

As can be seen by referring to FIG. 3 and the like above, the present embodiment adopts a configuration that drives the plurality of light-emitting elements 2a on the basis of the common power supply voltage Vs.

In this case, because the VCSEL light-emitting elements 2a exhibit individual variations in the forward voltage, to enable all of the light-emitting elements 2a in the emission section 2 to emit light appropriately, it is necessary to set the magnitude of the power supply voltage Vs to a voltage equal to or higher than the forward voltage of all of the light-emitting elements 2a.

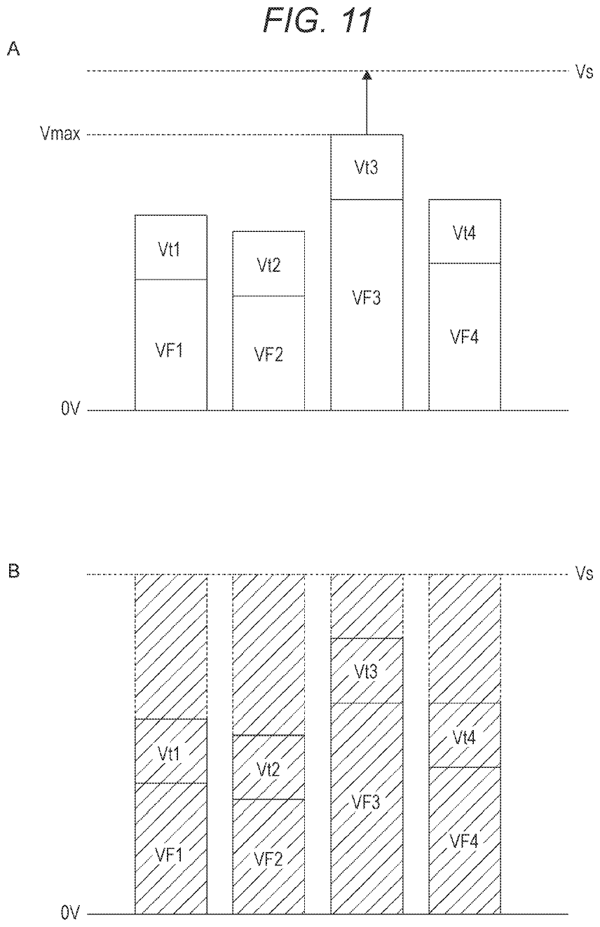

FIG. 11 is a diagram for explaining an example of setting the power supply voltage Vs in the related art.

In the configuration illustrated in FIGS. 3 and 4, because the driving circuit 30 (current mirror circuit) is provided to send a constant driving current Id to the light-emitting elements 2a, the power supply voltage Vs should be set with consideration for not only the forward voltage of each light-emitting element 2a, but also the operating voltage of each driving element Q1 in the driving circuit 30.

FIG. 11A schematically illustrates an example of setting the power supply voltage Vs with consideration for the forward voltages (VF1, VF2, VF3, and VF4) of the light-emitting elements 2a and the operating voltages (Vt1, Vt2, Vt3, and Vt4) of the driving elements Q1. Note that the operating voltages of the driving elements Q1 are considerably smaller than the forward voltages of the light-emitting elements 2a.

In the illustrated example, the forward voltage VF3 of the third light-emitting element 2a is the highest, and therefore in this case it is sufficient to set the power supply voltage Vs to a magnitude equal to or higher than the voltage (“Vmax” in the diagram) obtained by adding together the forward voltage VF3 and the operating voltage Vt3 (the operating voltage of the driving element Q1 connected to the third light-emitting element 2a). However, because it is difficult to ascertain the degree of variation among the forward voltages of the light-emitting elements 2a, in actuality, the power supply voltage Vs is set higher than the voltage Vmax to provide a margin.

In FIG. 11B, shading is used to schematically illustrate the power consumption in the case of setting the magnitude of the power supply voltage Vs according to the method described using FIG. 11A. As FIG. 11B demonstrates, with the setting method of the related art, there is a tendency for the power consumption to rise.

An object of the present embodiment is to attain a reduction in power consumption while also enabling all of the light-emitting elements 2a to emit light appropriately in a configuration that drives the plurality of light-emitting elements 2a on the basis of the common power supply voltage Vs.

For this reason, the present embodiment adopts a method of adjusting the power supply voltage Vs according to the forward voltage of the light-emitting elements 2a. Specifically, the power supply voltage Vs is adjusted according to the highest forward voltage among the plurality of light-emitting elements 2a.

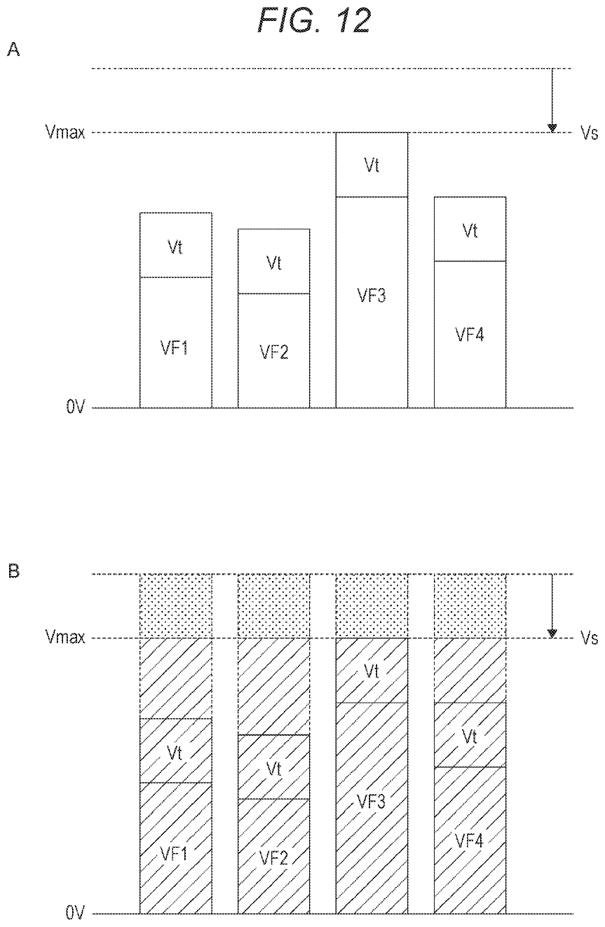

FIG. 12 is a diagram for explaining an example of adjusting the power supply voltage Vs as an embodiment.

As illustrated in the diagram, in the present embodiment, the magnitude of the power supply voltage Vs is adjusted to match the magnitude of the voltage Vmax. Specifically, the magnitude of the power supply voltage Vs is adjusted to the magnitude obtained by adding together the highest forward voltage among the plurality of light-emitting elements 2a and the operating voltage of the driving elements Q1. This adjustment is performed by the voltage adjustment section 41 illustrated in FIG. 3.

Here, the operating voltage of the driving elements Q1 is considerably smaller than the forward voltages (approximately from 2 V to 2.5 V, for example) of the light-emitting elements 2a, and the range of variation is also extremely narrow. Consequently, in this example, the driving elements Q1 are not treated as having individual operating voltages, and instead, the driving elements Q1 are treated as having a common operating voltage (hereinafter referred to as the “operating voltage Vt”).

At this point, if the operating voltage Vt is underestimated, there is a risk that the light-emitting element 2a having the highest forward voltage will not emit light, and therefore the operating voltage Vt is set relatively high to provide a margin.

In FIG. 12B, shading is used to schematically illustrate the power consumption in the case of adjusting the power supply voltage Vs like in FIG. 12A.

The diagram demonstrates that, compared to the case of FIG. 11B above, the magnitude of the power supply voltage Vs is minimized, and a reduction in power consumption is attained. Specifically, the power in the dotted portion of the diagram is reduced with respect to the case of FIG. 11B.

Also, in this example, by providing the driving circuit 30 with the switch SW for each light-emitting element 2a (each driving element Q1), it is possible to control the ON/OFF state of each light-emitting element 2a individually. In other words, individual driving of each light-emitting element 2a is possible.

By individually driving each light-emitting element 2a in this way, it is possible to turn on some of the light-emitting elements 2a while turning off the other light-emitting elements 2a, and the light-emitting element 2a having the highest forward voltage may be turned off.

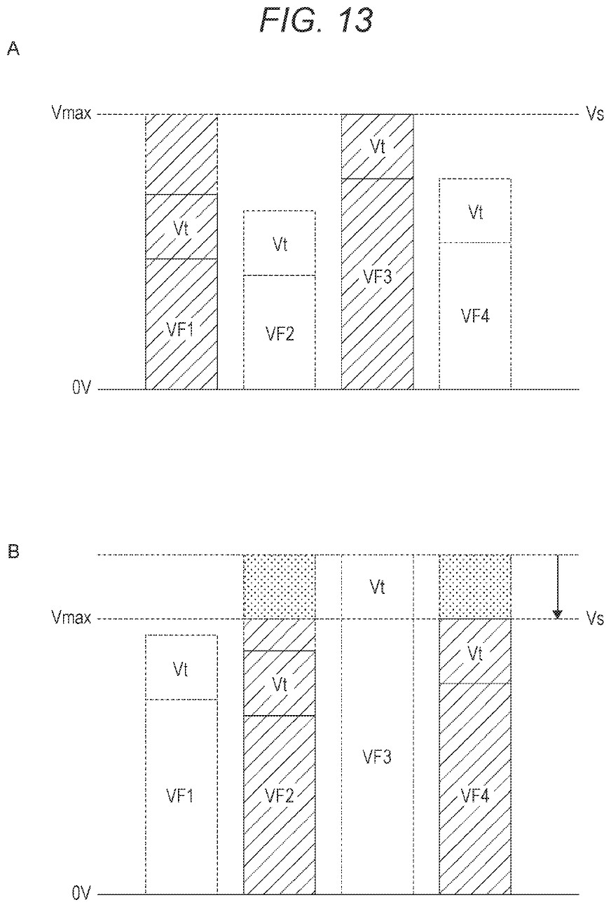

One such example is the case of causing the emission section 2 to emit light in a plurality of emission modes having different emission patterns (two-dimensional light/dark patterns). For example, in a first emission mode, the emission section 2 is made to emit light in an emission pattern that sets the first and third light-emitting elements 2a to an emitting state while setting the second and fourth light-emitting elements 2a to a non-emitting state, as illustrated in FIG. 13A, whereas in a second emission mode, the emission section 2 is made to emit light in an emission pattern that sets the second and fourth light-emitting elements 2a to an emitting state while setting the first and third light-emitting elements 2a to a non-emitting state, as illustrated in FIG. 13B.

In this case, if it is assumed that the forward voltage of the third light-emitting element 2a is the highest like in the example in the diagram, because the third light-emitting element 2a is turned off in the second emission mode illustrated in FIG. 13B, the power supply voltage Vs is lowered compared to the first emission mode. Specifically, during the second emission mode in this case, the power supply voltage Vs is adjusted according to the forward voltage of the fourth light-emitting element 2a having a lower forward voltage.

By configuring the plurality of light-emitting elements 2a to be individually drivable in this way, the light-emitting element 2a having the highest forward voltage may be turned off to create an opportunity to lower the power supply voltage Vs, and a reduction in power consumption may be attained.

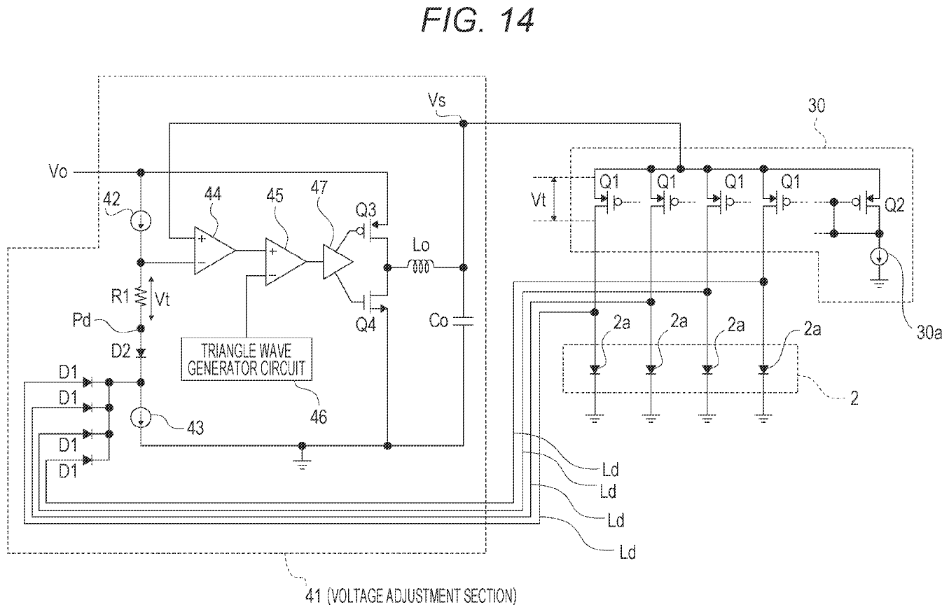

FIG. 14 is a diagram for explaining an exemplary internal configuration of a voltage adjustment section 41 for achieving the power supply voltage adjustment according to the embodiment described above. Note that in addition to the exemplary internal configuration of the voltage adjustment section 41, FIG. 14 also illustrates the driving circuit 30 and the emission section 2.

As illustrated in the diagram, the voltage adjustment section 41 is provided with a constant current source 42, a resistor R1, a diode D2, a constant current source 43, diodes D1 provided respectively for each of the detection lines Ld, a transistor Q3, a transistor Q4, an inductor Lo, a smoothing capacitor Co, a differential amplifier 44, a comparator 45, a triangle wave generator circuit 46, and a pre-driver circuit 47.

In the voltage adjustment section 41, the constant current source 42, the resistor R1, the diode D2, and the constant current source 43 are inserted in series between the supply line of the output voltage Vo from the DC/DC converter 40 and ground. As illustrated in the diagram, the constant current source 42 is inserted between the supply line of the output voltage Vo and one end of the resistor R1, while the diode D2 has an anode connected to the other end of the resistor R1 and a cathode connected to the constant current source 42. The constant current source 42 is inserted between the cathode of the diode D2 and ground.

As illustrated in the diagram, the diodes D1 are inserted respectively for each of the detection lines Ld, with the anode of each diode D1 being connected to an electrode of the corresponding light-emitting element 2a (in this case the anode, but in the case of adopting the driving circuit 30A illustrated in FIG. 4, the cathode), and the cathode of each diode D1 being connected to the node between the cathode of the diode D2 and the constant current source 42.

These diodes D1 function as backflow prevention elements that prevent the backflow of current from the supply line of the output voltage Vo toward the light-emitting elements 2a.

Also, in the voltage adjustment section 41, between the supply line of the output voltage Vo and ground, a series-connection circuit containing the constant current source 42, the resistor R1, the diode D2, and the constant current source 43 described above is inserted in parallel with a series-connection circuit containing the transistor Q3 and the transistor Q4.

In this example, FETs are used for the transistors Q3 and Q4, in which the transistor Q3 is a P-channel MOSFET and the transistor Q4 is an N-channel MOSFET.

The source of the transistor Q3 is connected to the node between the supply line of the output voltage Vo and the constant current source 42, while the drain is connected to the drain of the transistor Q4. The source of the transistor Q4 is connected to ground.

The node between the drains of the transistor Q3 and the transistor Q4 are connected to one end of the inductor Lo, while the other end of the inductor Lo is connected to the positive terminal of the smoothing capacitor Co. The negative terminal of the smoothing capacitor Co is connected to ground. The voltage across the smoothing capacitor Co is output by the voltage adjustment section 41 as the power supply voltage Vs.

In the differential amplifier 44, the power supply voltage Vs is input into the positive input terminal, while the voltage obtained at the node between the constant current source 42 and the resistor R1 is input into the negative input terminal.

In the comparator 45, the output voltage of the differential amplifier 44 is input into the non-inverting terminal while a triangle wave signal output by the triangle wave generator circuit 46 is input into the inverting terminal, and the comparator 45 outputs a pulse-width modulation (PWM) signal corresponding to the result of a comparison between the output voltage of the differential amplifier 44 and the triangle wave signal.

The pre-driver circuit 47 amplifies and outputs the PWM signal input by the comparator 45 to the gate of each of the transistor Q3 and the transistor Q4.

In the voltage adjustment section 41 having the above configuration, at the node between the resistor R1 and the diode D2 labeled “Pd” in the diagram, the highest forward voltage among the light-emitting elements 2a is obtained.

At this time, the forward voltages input through the detection lines Ld are lowered a degree by the diodes D1 for backflow prevention inserted on the detection lines Ld, but because the lowered amount of the voltage is recovered by the diode D2 inserted between the diodes D1 and the resistor R1, a voltage of a magnitude substantially equal to the highest voltage is obtained at the node Pd.

Additionally, in the voltage adjustment section 41, the resistance value of the resistor R1 is set such that a voltage substantially equal to the operating voltage Vt of the driving elements Q1 is obtained as the voltage across the resistor R1. Consequently, the voltage obtained by adding together the highest forward voltage among the light-emitting elements 2a and the operating voltage Vt, or in other words the voltage Vmax illustrated in FIGS. 12 and 13, is input into the inverting terminal of the differential amplifier 44.

With this arrangement, the duty cycle of the PWM signal output by the comparator 45 is adjusted according to the difference between the voltage Vmax and the power supply voltage Vs.

In the voltage adjustment section 41, the transistor Q3 and the transistor Q4 are alternately turned on/off on the basis of the PWM signal whose duty cycle is adjusted in this way. In the periods during which the transistor Q3 is turned on while the transistor Q4 is turned off, a charging current flows from the supply line of the output voltage Vo to the smoothing capacitor Co through the inductor Lo, whereas in the periods during which the transistor Q3 is turned off while the transistor Q4 is turned on, the smoothing capacitor Co is not charged, and is discharged instead.

By repeating such operations, the magnitude of the power supply voltage Vs is adjusted according to the duty cycle of the PWM signal. Specifically, the power supply voltage Vs is adjusted such that the magnitude of the power supply voltage Vs matches the voltage Vmax.

Here, in the voltage adjustment section 41 illustrated in FIG. 14, the plurality of detection lines Ld are combined into a single line to obtain the highest voltage on the single line. By adopting such a configuration, it is not necessary to provide a circuit for comparing the forward voltages to determine the highest voltage, and a simplification of the circuit configuration may be attained.

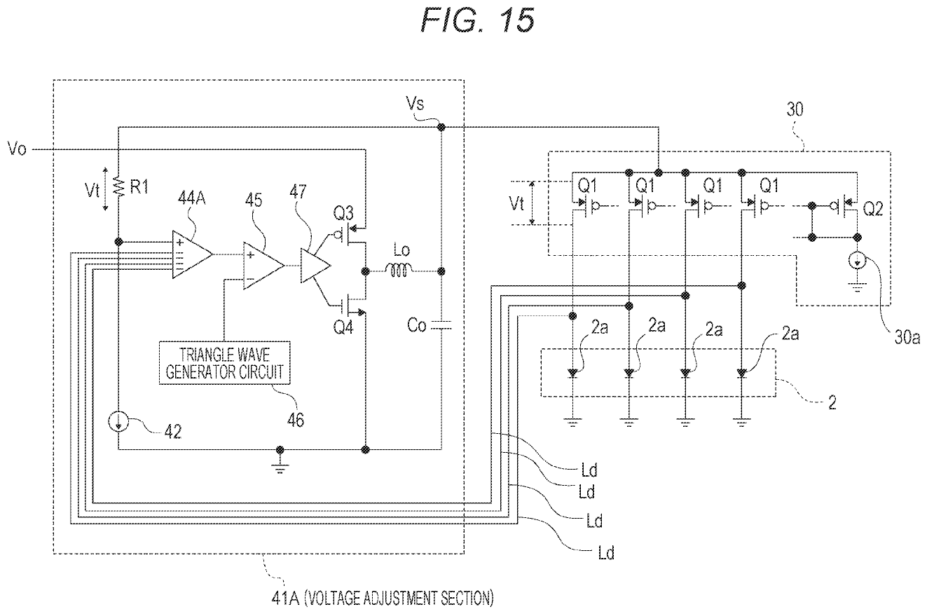

Note that the configuration for adjusting the power supply voltage Vs according to the highest forward voltage among the light-emitting elements 2a is not limited to the one illustrated in FIG. 14, and like the example illustrated as the voltage adjustment section 41A in FIG. 15 for instance, a configuration that inputs the forward voltage from each light-emitting element 2a into a differential amplifier 44A may also be adopted.

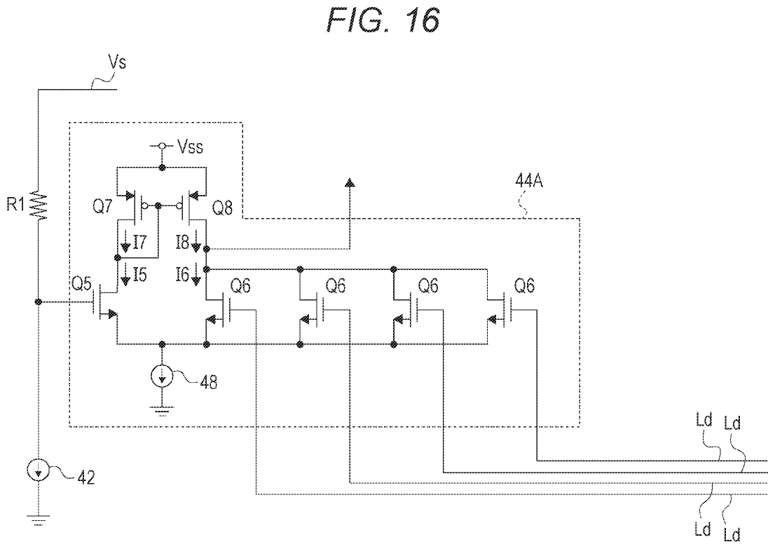

FIG. 16 illustrates an exemplary internal configuration of the differential amplifier 44A included in the voltage adjustment section 41A.

The differential amplifier 44A basically adopts a typical configuration combining a plurality of transistors. Transistors Q5 and Q6 are configured as transistors forming a differential pair, and transistors Q7 and Q8 are configured as transistors forming a current mirror circuit.

In this example, FETs are used for the transistors Q5, Q6, Q7, and Q8, in which the transistors Q5 and Q6 are N-channel MOSFETs and the transistors Q7 and Q8 are P-channel MOSFETs. As illustrated in the diagram, the respective sources of the transistors Q7 and Q8 are connected to the power supply voltage Vs, while the gates are connected to the drain of the transistor Q7 to form a current mirror circuit.

The drain of the transistor Q7 is connected to the drain of the transistor Q5. The source of the transistor Q5 is connected to ground through a constant current source 48.

The gate of the transistor Q5 functions as the positive input terminal of the differential amplifier 44A.

Here, in the voltage adjustment section 41A, the resistor R1 is inserted on a feedback line for inputting the power supply voltage Vs into the differential amplifier 44A. The resistor R1 in this case has one end connected to the node between the inductor Lo and the smoothing capacitor Co (see FIG. 15) and another end connected to ground through the constant current source 42.

The gate of the transistor Q5 is connected to the node between the resistor R1 and the constant current source 42, thereby feeding back the power supply voltage Vs through the resistor R1.

In the voltage adjustment section 41A, by feeding back the power supply voltage Vs into the differential amplifier 44A through the resistor R1 in this way, the power supply voltage Vs is adjusted according to the forward voltages of the light-emitting elements 2a and the operating voltage Vt of the driving elements Q1.

The gates of the transistors Q6 function as the negative input terminals of the differential amplifier 44A. In the differential amplifier 44A of this example, by providing the transistors Q6 respectively for each of the detection lines Ld, an output voltage corresponding to the difference between the highest voltage and the power supply voltage Vs (in this case, without the operating voltage Vt portion) is obtained.

Specifically, the forward voltage of the corresponding light-emitting element 2a is input into the gate of each transistor Q6 through the corresponding detection line Ld. The drain of each transistor Q6 is connected to the drain of the transistor Q8, while the source is connected to ground through the constant current source 48. The node between the drain of each transistor Q6 and the drain of the transistor Q8 functions as the output terminal of the differential amplifier 44A.

In the differential amplifier 44A having the above configuration, applying a gate voltage based on the power supply voltage Vs to the transistor Q5 turns on the transistor Q5, and by association, the transistors Q7 and Q8 also turn on. In this case, a current I5 flowing between the drain and source of the transistor Q5 matches a current I7 flowing between the source and drain of the transistor Q7, while in addition, because the transistors Q7 and Q8 form a current mirror circuit, a current I8 flowing between the source and drain of the transistor Q8 also has the same current value as the currents I5 and I7.

At this time, a current I6 flowing between the output terminal of the differential amplifier 44A (the node between each transistor Q6 and the drain of the transistor Q8) and the constant current source 48 matches the current between the drain and source of the transistor Q6 into which the highest forward voltage has been input from among the transistors Q6. Consequently, a current corresponding to the difference between the current I6 and the current I8 (which is equal to I5) flows to the output line of the differential amplifier 44A (the line connecting to the comparator 45), thereby producing at the output terminal of the differential amplifier 44A a voltage corresponding to the difference between the highest forward voltage and the voltage calculated by “power supply voltage Vs−operating voltage Dt”.

In the configuration illustrated as an example in FIG. 16, like the configuration illustrated in FIG. 14, it is not necessary to provide a circuit for comparing the forward voltages obtained from the detection lines Ld to determine the highest voltage, and a simplification of the circuit configuration may be attained.

Note that although FIG. 16 illustrates an example of a configuration that uses the driving circuit 30 connected on the anode side of the light-emitting elements 2a, it is also possible to take a configuration using the driving circuit 30A connected on the cathode side of the light-emitting elements 2a, as illustrated in FIG. 4.

Furthermore, it is also possible to take a configuration using the voltage adjustment section 41A instead of the voltage adjustment section 41.

Here, as the description referencing diagrams such as FIGS. 14 and 16 demonstrates, in the present embodiment, when adjusting the power supply voltage Vs, it is necessary to dispose a number of detection lines Ld equal to the number of light-emitting elements 2a between the driving section 3 and the power supply circuit 4 (voltage adjustment section). In the illustrated examples, the number of light-emitting elements 2a is taken to be “4”, but in actuality many more light-emitting elements 2a, such as hundreds or thousands, are expected to be provided.

In consideration of this point, in the case where the driving section 3 and the power supply circuit 4 are configured as separate chips like in FIGS. 5A and 7A for example, it is necessary to dispose a large number of detection lines Ld between the chips, which may lead to an enlarged size of the substrate B on which to mount the chips or a reduced degree of design freedom.

On the other hand, if the driving section 3 and the power supply circuit 4 are formed in the same chip (chip Cp34) like in FIGS. 5B and 7B, because each detection line Ld can be formed by in-chip wiring, the detection lines Ld can be provided without being disposed between chips, and a reduced size of the substrate B and an increased degree of design freedom may be attained.

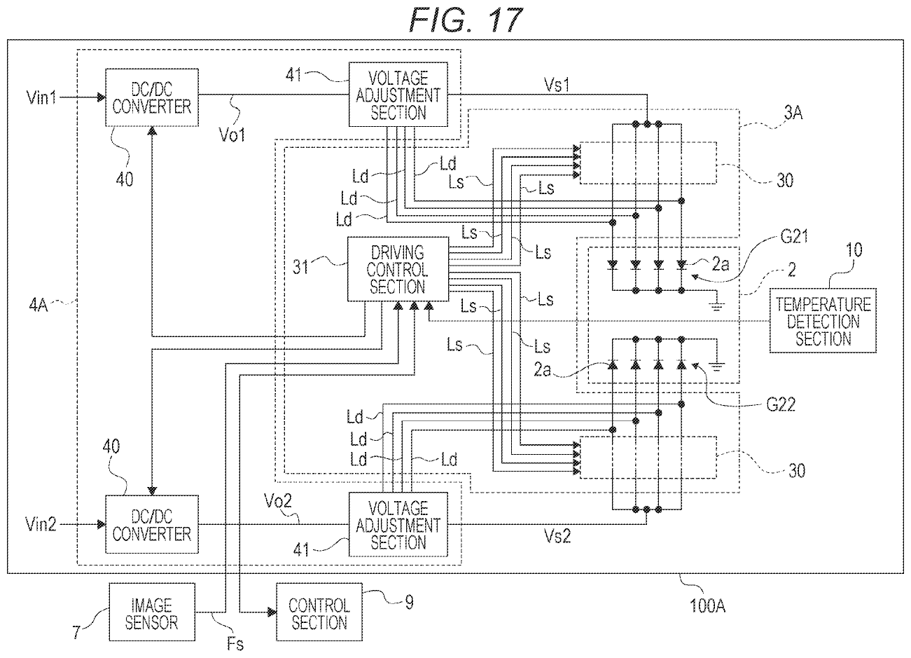

FIG. 17 illustrates an exemplary configuration of a light source apparatus 100A according to a modification.

In the light source apparatus 100A, the emission section 2 includes a plurality of light-emitting element groups G, and the power supply voltage Vs is adjusted for each light-emitting element group G.

As illustrated in the diagram, the light source apparatus 100A differs from the light source apparatus 100 by being provided with a power supply circuit 4A instead of the power supply circuit 4 and a driving section 3A instead of the driving section 3. In this case, the emission section 2 has a plurality of light-emitting element groups G (in the example in the diagram, the two groups of a light-emitting element group G21 and a light-emitting element group G22), each including a plurality of light-emitting elements 2a. Note that the light-emitting element groups G may include the same number or different numbers of the light-emitting elements 2a.

The power supply circuit 4A includes the DC/DC converter 40 and the voltage adjustment section 41 for each light-emitting element group G. A separate input voltage Vin is supplied to each DC/DC converter 40, such that an input voltage Vin1 is supplied to one DC/DC converter 40 and an input voltage Vin2 is supplied to the other DC/DC converter 40 as illustrated in the diagram.

The output voltage Vo from the corresponding DC/DC converter 40 is input into each voltage adjustment section 41. In the diagram, the output voltage Vo from one DC/DC converter 40 is labeled “Vo1”, and the output voltage Vo from the other DC/DC converter 40 is labeled “Vo2”. Also, the power supply voltages Vs respectively output by the voltage adjustment sections 41 are distinguished as “Vs1” and “Vs2”.

The forward voltages of each of the light-emitting elements 2a in the corresponding light-emitting element group G are input through the corresponding detection lines Ld into each voltage adjustment section 41.

The driving section 3A is provided with a plurality of driving circuits 30 that accept the input of the power supply voltage Vs from the respectively different voltage adjustment sections 41 and drive the light-emitting elements 2a of the corresponding light-emitting element group G (in FIG. 17, the internal configuration of the driving circuits 30 is omitted for convenience).

The driving control section 31 in this case controls the ON/OFF state of the switches SW in each driving circuit 30.

In the light source apparatus 100A illustrated in FIG. 17, the power supply voltage Vs shared within each light-emitting element group G is adjusted individually for each light-emitting element group G by each voltage adjustment section 41. In the case of taking such a configuration, to enable all of the light-emitting elements 2a in the emission section 2 to emit light appropriately, it is sufficient to adjust each power supply voltage Vs to suit the highest forward voltage in the corresponding light-emitting element group G to be supplied with each power supply voltage Vs, and it is not necessary to adjust each power supply voltage Vs to suit the highest forward voltage from among all of the light-emitting elements 2a in the emission section 2.

Consequently, if the respective highest forward voltages of the light-emitting element groups G are not the same, the power supply voltage Vs of one or some of the light-emitting element groups G can be lowered below the highest voltage among the forward voltages of all of the light-emitting elements 2a in the emission section 2, and compared to the case of adopting a configuration that supplies a common power supply voltage Vs to the light-emitting element groups G, the effect of reducing the power consumption can be enhanced.

Here, in the configuration illustrated in FIG. 17, the light-emitting element groups G in the emission section 2 can be distinguished according to the properties, the purpose or the like of the light-emitting elements 2a. For example, in the case where the properties of the light-emitting elements 2a are different for each light-emitting element group G, the forward voltages of the light-emitting elements 2a in each of the light-emitting element groups G may be relatively largely different from each other. In this case, the differences in the power supply voltage Vs between the light-emitting element groups G increase, and the effect of reducing the power consumption can be enhanced over the case where a common power supply voltage Vs is shared by all of the light-emitting elements 2a in the emission section 2.

Note that in the description so far, the power supply voltage Vs is adjusted by treating the highest forward voltage as a reference, but the power supply voltage Vs is not limited to being adjusted with reference to the highest voltage, and may also be adjusted by treating the second-highest forward voltage as a reference, or by treating the forward voltage(s) at or above a predetermined threshold as a reference, for example.

For example, even in the case where the second-highest forward voltage or the forward voltage(s) at or above a predetermined threshold is treated as the reference, by adopting a configuration that adds a marginal voltage like the operating voltage Vt to the forward voltage acting as a reference and provides the result as feedback, it is possible to set the magnitude of the power supply voltage Vs to the highest voltage or higher by setting the marginal voltage. In other words, it is possible to cause all of the light-emitting elements 2a that share the power supply voltage Vs to emit light appropriately.

<7. Summary of Embodiment and Modifications>

A light source apparatus (the distance measuring apparatus 1, the light source apparatuses 100 and 100A) as the embodiment described above includes an emission section (2) in which a plurality of vertical-cavity surface-emitting laser light-emitting elements (2a) is arrayed, and a voltage adjustment section (41 or 41A) configured to adjust a power supply voltage used in common to drive the plurality of light-emitting elements in the emission section according to a forward voltage of the light-emitting elements.

This arrangement makes it possible to adjust the power supply voltage appropriately according to the forward voltage of the light-emitting elements, such as by raising the power supply voltage if the forward voltage of the light-emitting elements is high and lowering the power supply voltage if the forward voltage of the light-emitting elements is low.

Consequently, a reduction in power consumption may be attained while also enabling all light-emitting elements to emit light appropriately in a configuration that drives a plurality of vertical-cavity surface-emitting laser light-emitting elements on the basis of a common power supply voltage.

In addition, in the light source apparatus as an embodiment, the voltage adjustment section adjusts the power supply voltage according to a highest forward voltage among the plurality of light-emitting elements.

With this arrangement, the common power supply voltage is adjusted according to the forward voltage of the light-emitting element having the highest forward voltage.

Consequently, the power consumption can be kept to a minimum while also causing all of the light-emitting elements that share the power supply voltage to emit light appropriately.

Further, the light source apparatus as an embodiment includes a driving section (3 or 3A) configured to drive the plurality of light-emitting elements individually on the basis of the power supply voltage.

With this arrangement, it is possible to turn on some of the plurality of light-emitting elements sharing the power supply voltage while turning off the other light-emitting elements, and the light-emitting element having the highest forward voltage may be turned off. By turning off the light-emitting element having the highest forward voltage, the power supply voltage is adjusted according to the forward voltage of the light-emitting elements having a lower forward voltage.

Consequently, compared to a case where the plurality of light-emitting elements are not individually drivable, an opportunity for lowering the power supply voltage is created, and therefore a reduction in power consumption may be attained.

Furthermore, the light source apparatus as an embodiment is provided with a current mirror circuit (driving elements Q1, switching element Q2, and constant current source 30a) that sends a constant current to the plurality of light-emitting elements on the basis of the power supply voltage.

With this arrangement, it is not necessary to use a power supply circuit with a constant current control function to send a constant current to the light-emitting elements.

Consequently, a simplification of the circuit configuration may be attained.

Also, in the light source apparatus as an embodiment, the current mirror circuit is connected on the anode side of the light-emitting elements, and the voltage adjustment section adjusts the power supply voltage according to the voltage at the anode of the light-emitting elements.

With this arrangement, it is possible to adjust the power supply voltage appropriately according to the forward voltage of the light-emitting elements in a case where the current mirror circuit is connected on the anode side of the light-emitting elements.

Further, in the light source apparatus as an embodiment, the current mirror circuit is connected to a cathode side of the light-emitting elements, and the voltage adjustment section is configured to adjust the power supply voltage according to a voltage at a cathode of the light-emitting elements.

With this arrangement, it is possible to adjust the power supply voltage appropriately according to the forward voltage of the light-emitting elements in a case where the current mirror circuit is connected on the cathode side of the light-emitting elements.

Furthermore, in the light source apparatus as an embodiment, the voltage adjustment section adjusts the power supply voltage according to the forward voltage of the light-emitting elements and an operating voltage of a driving element in the current mirror circuit (Q1).

With this arrangement, the power supply voltage is adjusted appropriately according to the forward voltage of the light-emitting elements and the operating voltage of the driving elements, in correspondence with the case of providing the current mirror circuit.

Consequently, it is possible to enhance the effect of preventing a situation in which some light-emitting elements (light-emitting elements having a high forward voltage) among the plurality of light-emitting elements that share the power supply voltage do not emit light.

Also, the light source apparatus as an embodiment is provided with a driving section (3 or 3A) that drives the plurality of light-emitting elements on the basis of power supply voltage, and the driving section and the voltage adjustment section are formed in the same chip.

This arrangement makes it possible to use in-chip wiring to form the detection lines for detecting and inputting the forward voltage of each of the light-emitting elements into the voltage adjustment section.

Consequently, a large number of detection lines do not have to be disposed between chips, and a reduced size of the substrate on which to mount the chip and an increased degree of design freedom may be attained.

Further, in the light source apparatus (100A) as an embodiment, the emission section includes a plurality of light-emitting element groups, each including a plurality of the light-emitting elements (G), and the voltage adjustment section adjusts a power supply voltage shared within each light-emitting element group according to the forward voltage for each light-emitting element group.

In the case of taking a configuration that adjusts a power supply voltage shared in common within a light-emitting element group individually for each light-emitting element group in this way, to enable all of the light-emitting elements in the emission section to emit light appropriately, it is sufficient to adjust each power supply voltage to suit the highest forward voltage in the corresponding light-emitting element group to be supplied with each power supply voltage, and it is not necessary to adjust each power supply voltage to suit the highest forward voltage from among all of the light-emitting elements in the emission section.

Consequently, if the respective highest forward voltages of the light-emitting element groups are not the same, the power supply voltage of one or some of the light-emitting element groups can be lowered below the highest voltage among the forward voltages of all of the light-emitting elements in the emission section, and compared to the case of adopting a configuration that supplies a common power supply voltage to the light-emitting element groups, the effect of reducing the power consumption can be enhanced.

Also, an adjustment method as an embodiment is a method of adjusting the power supply voltage used in common to drive a plurality of light-emitting elements in an emission section in which a plurality of vertical-cavity surface-emitting laser light-emitting elements is arrayed, in which the power supply voltage is adjusted according to the forward voltage of the light-emitting elements.

Furthermore, a sensing module as an embodiment includes the light source apparatus as an embodiment, and an image sensor (7) that captures an image by receiving light that is emitted by the emission section (2) provided in the light source apparatus and then reflected by a subject (for example, see a configuration illustrated in FIG. 7).

Action and effects similar to the light source apparatus as an embodiment described above may also be obtained with an adjustment method and a sensing module as such an embodiment.

Note that the above describes an example of a configuration in which the switch SW is provided for each light-emitting element 2a to enable individual control of each light-emitting element 2a, but in the present technology, a configuration enabling the individual driving of each light-emitting element 2a is not essential.

Additionally, although the above describes an example in which the present technology is applied to a distance measuring apparatus, the present technology is not limited to being applied to a light source for distance measurement.

Note that the effects described in this specification are merely non-limiting examples, and there may be other effects.

<8. Present Technology>

Note that the present technology may be configured as below.

(1)

A light source apparatus including:

an emission section in which a plurality of vertical-cavity surface-emitting laser light-emitting elements is arrayed; and

a voltage adjustment section configured to adjust a power supply voltage used in common to drive the plurality of light-emitting elements in the emission section according to a forward voltage of the light-emitting elements.

(2)

The light source apparatus according to (1), in which

the voltage adjustment section

is configured to adjust the power supply voltage according to a highest forward voltage among the plurality of light-emitting elements.

(3)

The light source apparatus according to (1) or (2), further including:

a driving section configured to drive the plurality of light-emitting elements individually on the basis of the power supply voltage.

(4)

The light source apparatus according to any one of (1) to (3), further including:

a current mirror circuit configured to send a constant current to the plurality of light-emitting elements on the basis of the power supply voltage.

(5)

The light source apparatus according to (4), in which

the current mirror circuit is connected to an anode side of the light-emitting elements, and

the voltage adjustment section

is configured to adjust the power supply voltage according to a voltage at an anode of the light-emitting elements.

(6)

The light source apparatus according to (4), in which

the current mirror circuit is connected to a cathode side of the light-emitting elements, and

the voltage adjustment section

is configured to adjust the power supply voltage according to a voltage at a cathode of the light-emitting elements.

(7)

The light source apparatus according to any one of (4) to (6), in which

the voltage adjustment section

is configured to adjust the power supply voltage according to the forward voltage of the light-emitting elements and an operating voltage of a driving element in the current mirror circuit.

(8)

The light source apparatus according to any one of (1) to (7), further including:

a driving section configured to drive the plurality of light-emitting elements on the basis of the power supply voltage, in which

the driving section and the voltage adjustment section are formed in a same chip.

(9)

The light source apparatus according to any one of (1) to (8), in which

the emission section includes a plurality of light-emitting element groups, each including a plurality of

the light-emitting elements, and

the voltage adjustment section is configured to adjust a power supply voltage shared within each light-emitting element group according to the forward voltage for each light-emitting element group.

### REFERENCE SIGNS LIST

1 Distance measuring apparatus
2 Emission section
2a Light-emitting element
3, 3A Driving section
4, 4A Power supply circuit
5 Emission-side optical system
6 Imaging-side optical system
7 Image sensor
8 Image processing section
9 Control section
9a Distance measurement section
Cp2, Cp3, Cp4, Cp34, Cp7 Chip
30, 30A Driving circuit
31 Driving control section
Q1 Driving element
Q2 Current control element
SW Switch
DC/DC converter
41, 41A Voltage adjustment section
Vs Power supply voltage
Vd Driving voltage
Ld Detection line
G21, G22 Light-emitting element group
42, 43, 48 Constant current source
44, 44A Differential amplifier
Comparator
46 Triangle wave generator circuit
47 Pre-driver circuit
Q3, Q4 Switching element
R1 Resistor
D1, D2 Diode
Q5 to Q8 Transistor
100, 100A Light source apparatus

1. A light source apparatus comprising:
an emission section in which a plurality of vertical-cavity surface-emitting laser light-emitting elements is arrayed; and
a voltage adjustment section configured to adjust a power supply voltage used in common to drive the plurality of light-emitting elements in the emission section according to a forward voltage of the light-emitting elements.

2. The light source apparatus according to claim 1, wherein
the voltage adjustment section
is configured to adjust the power supply voltage according to a highest forward voltage among the plurality of light-emitting elements.

3. The light source apparatus according to claim 1, further comprising:
a driving section configured to drive the plurality of light-emitting elements individually on a basis of the power supply voltage.

4. The light source apparatus according to claim 1, further comprising:
a current mirror circuit configured to send a constant current to the plurality of light-emitting elements on a basis of the power supply voltage.

5. The light source apparatus according to claim 4, wherein
the current mirror circuit is connected to an anode side of the light-emitting elements, and
the voltage adjustment section
is configured to adjust the power supply voltage according to a voltage at an anode of the light-emitting elements.

6. The light source apparatus according to claim 4, wherein
the current mirror circuit is connected to a cathode side of the light-emitting elements, and
the voltage adjustment section
is configured to adjust the power supply voltage according to a voltage at a cathode of the light-emitting elements.

7. The light source apparatus according to claim 4, wherein
the voltage adjustment section
is configured to adjust the power supply voltage according to the forward voltage of the light-emitting elements and an operating voltage of a driving element in the current mirror circuit.

8. The light source apparatus according to claim 1, further comprising:
a driving section configured to drive the plurality of light-emitting elements on a basis of the power supply voltage, wherein
the driving section and the voltage adjustment section are formed in a same chip.

9. The light source apparatus according to claim 1, wherein
the emission section includes a plurality of light-emitting element groups, each including a plurality of the light-emitting elements, and
the voltage adjustment section
is configured to adjust a power supply voltage shared within each light-emitting element group according to the forward voltage for each light-emitting element group.

10. An adjustment method comprising:
adjusting a power supply voltage used in common to drive a plurality of light-emitting elements in an emission section in which a plurality of vertical-cavity surface-emitting laser light-emitting elements is arrayed, the power supply voltage being adjusted according to a forward voltage of the light-emitting elements.

11. A sensing module comprising:
a light source apparatus including an emission section in which a plurality of vertical-cavity surface-emitting laser light-emitting elements is arrayed, and a voltage adjustment section configured to adjust a power supply voltage used in common to drive the plurality of light-emitting elements in the emission section according to a forward voltage of the light-emitting elements; and
an image sensor configured to capture an image by receiving light emitted by the emission section and reflected by a subject.
